(19) United States
(12) Patent Application Publication
(10) Pub. No.: US 2025/0031418 A1
(43) Pub. Date: Jan. 23, 2025

(54) GATE-ALL-AROUND FIELD EFFECT TRANSISTOR HAVING TRENCH INTERNAL SPACER, AND METHOD FOR MANUFACTURING SAME

(71) Applicant: Samsung Electronics Co., Ltd., Suwon-si, Gyeonggi-do (KR)

(72) Inventors: Rock-Hyun BAEK, Pohang-si (KR); Jin-Su JEONG, Daegu-si (KR); Jun-Sik YOON, Pohang-si (KR)

(73) Assignee: Samsung Electronics Co., Ltd., Suwon-si, Gyeonggi-do (KR)

(21) Appl. No.: 18/684,436

(22) PCT Filed: May 12, 2022
(86) PCT No.: PCT/KR2022/006837

§ 371 Date: Feb. 16, 2024

(30) Foreign Application Priority Data
Aug. 18, 2021 (KR) 10-2021-0108414

(51) Int. Cl. H01L 29/06; H01L 29/10; H01L 29/16; H01L 29/423; H01L 29/49; H01L 29/66; H01L 29/775; H01L 29/786

(52) U.S. Cl. CPC H01L 29/0653; H01L 29/1083; H01L 29/0673; H01L 29/16; H01L 29/42392; H01L 29/4975; H01L 29/66439; H01L 29/775; H01L 29/78696

(57) ABSTRACT

The present disclosure discloses a gate-all-around field effect transistor which not only can suppress the occurrence of punch through in the lower end of the substrate and direct leakage of current from the source region/drain region into the lower ends of the channels, but also can facilitate heat release of the substrate by forming trench inner spacers (TIS) and thus preventing source region/drain region impurities from diffusing into the substrate, and a method for manufacturing the same.

### TECHNICAL FIELD

The present disclosure relates to a gate-all-around field effect transistor having trench inner spacers and a method for manufacturing the same.

### BACKGROUND ART

Various 3D structure devices such as FinFET and gate-all-around (GAA) field effect transistor are currently being studied in order to overcome the short-channel effect by developing a 3D structure semiconductor device.

Among them, a 3D gate-all-around (GAA) field effect transistor means a structure in which all four sides of channels are surrounded by gates. Unlike in the FinFET, in the GAA field effect transistor, it is possible to stack channels. Therefore, although the number of channels is increased, an area of a lower end portion of a substrate that is occupied by an FET is not correspondingly increased. Thus, the GAA field effect transistor is advantageous in realizing miniaturization and in easily controlling the width of a channel and the number of channels.

In a manufacturing process of a conventional GAA transistor, a recess etching process is performed to form a source region/a drain region. In such an etching process, an over-etch phenomenon occurs unintendedly due to process variation. At this point, T_{SD} means the over-etched source region/drain region recess thickness.

The present inventors have proposed a solution thereto along with such a problem in NSFETs through Non-Patent Documents 1 and 2. According to these documents, it is disclosed that the deeper the T_{SD}, the more impurities in the source region/drain region diffuse toward the substrate, and accordingly, a large amount of leakage current occurs at the portion under the channel that is not controlled by the gate due to the punch-through phenomenon.

The deeper the T_{SD}, the more leakage current and parasitic capacitance occur. In particular, it is disclosed that the leakage current caused by the T_{SD} causes a serious increase in static power consumption and, in severe cases, causes a serious problem in that it cannot function as a semiconductor device.

In order to prevent leakage current due to over-etched source region/drain region recesses through Patent Document 1, the present applicant has proposed BOX Scheme technology of buried oxide (BOX) depositing an insulator (SiO₂ or Si₃N₄) under the source region/drain region. However, when an insulator is deposited under the source region/drain region in such a BOX scheme technology, it is difficult to release heat generated in a device through a Si substrate due to the thermal conductivity of the insulator lower than that of Si, resulting in deterioration of the device.

(Patent Document 1) Korea Patent No. 10-2133208 B1 (issued on Jul. 14, 2020)

(Non-patent Document 1) Jun-Sik Yoon et al., Punch-through-stopper Free Nanosheet FETs with Crescent Inner-spacer and Isolated Source/drain region, 14 Mar. 2019, IEEE Access vol. 7, p38593-38596

(Non-patent Document 2) J. Jeong, J.-S. Yoon, S. Lee and R.-H. Baek, Comprehensive Analysis of Source and Drain Recess Depth Variations on Silicon Nanosheet FETs for Sub 5-nm Node SoC Application, February 2020,IEEE Access, vol. 8, p35873-35881

### DISCLOSURE

### Technical Problem

The present applicant conducted research on devices having various structures that are capable of being formed without a significant change to existing processes, in order to effectively prevent leakage current and achieve the effect of releasing heat through a substrate at the same time. As a result, the effects of suppressing the leakage current and releasing heat through a substrate compared to the BOX Scheme technology could be secured at the same time regardless of the over-etched TSD when the trench inner spacers connected to the inner spacers are formed.

Accordingly, an object of the present disclosure is to provide a gate-all-around field effect transistor having trench inner spacers and a method for manufacturing the same.

### Technical Solution

One embodiment of the present disclosure provides a gate-all-around field effect transistor including: a substrate in which a first groove and a second groove that have a trench structure are formed; a source region/a drain region formed to be spaced apart from each other on the substrate; a plurality of channels connecting the source region/drain region; a plurality of gate stacks having a gate-all-around (GAA) structure surrounding the circumference of at least some of the channels; first inner spacers included between the source region/drain region and the gate stacks; second inner spacers located on the bottom of a lowermost channel among the plurality of channels and included between the source region/drain region and a lowermost gate stack; and trench inner spacers connected to the second inner spacers and vertically extended up to the inside of the first groove and the second groove.

Another embodiment of the present disclosure provides a gate-all-around field effect transistor including: a substrate; a punch through stopper (PTS) which is positioned on the substrate and in which a first groove and a second groove that have a trench structure are formed; a source region/a drain region formed to be spaced apart from each other on the punch through stopper (PTS); a plurality of channels connecting the source region/drain region; a plurality of gate stacks having a gate-all-around (GAA) structure surrounding the circumference of at least some of the channels; first inner spacers included between the source region/drain region and the gate stacks; second inner spacers located on the bottom of a lowermost channel among the plurality of channels and included between the source region/drain region and a lowermost gate stack; and trench inner spacers connected to the second inner spacers and vertically extended up to the inside of the first groove and the second groove.

At this point, a thickness of a portion, between the first groove and the second groove, of the substrate may be the same as or different from that of the other portion of the substrate.

Further, the height H_{TIS} of the trench inner spacers may satisfy Equation 1 below.

$${H}_{TIS} = {T}_{SD} + {L}_{IS} \qquad [ Equation 1 ]$$

where H_{TIS} is a vertical length of the TIS with respect to the TIS sidewalls in contact with the source region/drain region, T_{SD} is an over-etched source region/drain region recess depth, and L_{IS} is a horizontal length of the second inner spacer, and is equal to a vertical length from the lowermost point in the vertical direction on the TIS sidewalls in contact with the source region/drain region to the top surface of the substrate located on the bottom of the source region/drain region.

Specifically, T_{SD} may be 0 nm to 200 nm. In addition, L_{IS} may be more than 0 nm and not more than 100 nm.

Further, the trench inner spacers may include one or more insulating materials selected from the group consisting of SiO₂, Al₂O₃, HfO₂, ZrO₂, Si₃N₄, and perovskite oxide.

Still another embodiment of the present disclosure provides a method for manufacturing a gate-all-around field effect transistor including steps of: performing patterning to form a trench structured groove on the top of one side of a substrate; forming a plurality of channels and sacrificial layers alternately arranged on the substrate; forming a shallow trench isolation (STI) region and patterning the channels and sacrificial layers; forming a dummy gate; vertically etching the channels and the sacrificial layers in order to form a source region/a drain region; selectively etching portions of the sacrificial layers in contact with the channels; depositing an insulating material on the inside of the trench structured groove of the substrate and on the etched regions of the selectively etched sacrificial layers to form inner spacers and trench inner spacers connected to the inner spacers and vertically extended up to the inside of the trench structured groove formed in the substrate; forming a source region/a drain region by a selective epitaxial growth process; and forming a replacement metal gate.

Yet another embodiment of the present disclosure provides a method for manufacturing a gate-all-around field effect transistor including: forming a punch through stopper (PTS) on a substrate; performing patterning to form a trench structured groove on the top of one side of the punch through stopper (PTS); forming a plurality of channels and sacrificial layers alternately arranged on the punch through stopper (PTS); forming a shallow trench isolation (STI) region and patterning the channels and sacrificial layers; forming a dummy gate; vertically etching the channels and the sacrificial layer in order to form a source region/a drain region; selectively etching portions of the sacrificial layers in contact with the channels; depositing an insulating material on the inside of the trench structured groove of the punch through stopper (PTS) and on the etched regions of the selectively etched sacrificial layers to form inner spacers and trench inner spacers connected to the inner spacers and vertically extended up to the inside of the trench structure formed on the punch through stopper (PTS); forming a source region/a drain region by a selective epitaxial growth process; and forming a replacement metal gate.

At this point, when the channels and the sacrificial layers are vertically etched, the region where the source region/drain region are formed can be additionally etched compared to the region in contact with the sacrificial layers of the substrate.

Further, the height H_{TIS} of the trench inner spacers may be formed so as to satisfy Equation 1 below.

$${H}_{TIS} = {T}_{SD} + {L}_{IS} \qquad [ Equation 1 ]$$

where H_{TIS} is a vertical length of the TIS with respect to the TIS sidewalls in contact with the source region/drain region, T_{SD} is an over-etched source region/drain region recess depth, and L_{IS} is a horizontal length of the second inner spacer, and is equal to a vertical length from the lowermost point in the vertical direction on the TIS sidewalls in contact with the source region/drain region to the top surface of the substrate located on the bottom of the source region/drain region.

Specifically, T_{SD} may be 0 nm to 200 nm. In addition, L_{IS} may be more than 0 nm and not more than 100 nm.

Further, the trench inner spacers may be formed through the deposition of one or more insulating materials selected from the group consisting of SiO₂, Al₂O₃, HfO₂, ZrO₂, Si₃N₄, and perovskite oxide.

### Advantageous Effects

The GAAFET device including trench inner spacers (TIS) according to the present disclosure can prevent leakage current from occurring under the channels that cannot be controlled by a gate, using the TIS.

Further, since, as the source region/drain region recesses become deeper, the depth of the trench inner spacers also becomes deeper at the same time, there is robustness of source region/drain region recess process variables.

Further, a technique for preventing leakage current at the part under the channels by depositing a dielectric layer on the lower ends of the source region/drain region has been previously invented, but compared to the previous invention, the present technique has an advantage in that heat release to the substrate is easy.

Such a technique may be applied to all semiconductor products that utilize three-dimensional GAAFET devices, and it may be expected to increase production yield and reduce costs by reduced power consumption due to reduced leakage current, and the robustness of source region/drain region recess process variables.

In addition, since the trench patterning process for forming the trench inner spacers (TIS) is performed at the beginning of the manufacturing process of the device, the patterning consistency can be precisely controlled so that there is an advantage in that the technology application possibility and completeness are very high. In addition, regarding the other processing processes, existing processing processes can be utilized without any change. In this respect, the likelihood of application of the present technology is also high.

### BRIEF DESCRIPTION OF DRAWINGS

FIG. 1 is a cross-sectional view showing a GAAFET according to one embodiment of the present disclosure.

FIG. 2 is a cross-sectional view showing a GAAFET according to another embodiment of the present disclosure.

FIG. 3 is a cross-sectional view showing a GAAFET according to yet another embodiment of the present disclosure.

FIG. 4 is a cross-sectional view showing a GAAFET according to still another embodiment of the present disclosure.

FIG. 5 is a diagram for explaining source region/drain region recesses.

FIG. 6 is a diagram for explaining a manufacturing method of a GAAFET device of the present disclosure.

FIGS. 7 to 19 are views showing a manufacturing method of the GAAFET device of FIG. 2 according to one embodiment of the present disclosure.

FIG. 20 is a diagram for explaining a manufacturing method of a GAAFET device of the present disclosure.

FIGS. 21 to 33 are views showing a manufacturing method of the GAAFET device of FIG. 4 according to one embodiment of the present disclosure.

### BEST MODE FOR CARRYING OUT THE INVENTION

One embodiment of the present disclosure provides a gate-all-around field effect transistor including: a substrate in which a first groove and a second groove that have a trench structure are formed; a source region/a drain region formed to be spaced apart from each other on the substrate; a plurality of channels connecting the source region/drain region; a plurality of gate stacks having a gate-all-around (GAA) structure surrounding the circumference of at least some of the channels; first inner spacers included between the source region/drain region and the gate stacks; second inner spacers located on the bottom of a lowermost channel among the plurality of channels and included between the source region/drain region and a lowermost gate stack; and trench inner spacers connected to the second inner spacers and vertically extended up to the inside of the first groove and the second groove.

Another embodiment of the present disclosure provides a gate-all-around field effect transistor including: a substrate; a punch through stopper (PTS) which is positioned on the substrate and in which a first groove and a second groove that have a trench structure are formed; a source region/a drain region formed to be spaced apart from each other on the punch through stopper (PTS); a plurality of channels connecting the source region/drain region; a plurality of gate stacks having a gate-all-around (GAA) structure surrounding the circumference of at least some of the channels; first inner spacers included between the source region/drain region and the gate stacks; second inner spacers located on the bottom of a lowermost channel among the plurality of channels and included between the source region/drain region and a lowermost gate stack; and trench inner spacers connected to the second inner spacers and vertically extended up to the inside of the first groove and the second groove.

### Mode for Carrying Out the Invention

The above-mentioned objects, other objects, features, and advantages of the present disclosure will be easily understood through the following preferred embodiments that will be described below with reference to the accompanying drawings. However, the present disclosure is not limited to the embodiments described herein and may also be embodied in other forms. Rather, the embodiments introduced herein are provided so that the disclosed content will be thorough and complete, and the spirit of the present disclosure will be sufficiently conveyed to those skilled in the art.

In the present specification, when a certain film (or layer) is referred to as being on other film (or layer) or substrate, it may be directly formed on the other film (or layer) or substrate, or a third film (or layer) may be interposed therebetween. In addition, the size, thickness, and the like of constituent elements in the drawings are exaggerated for clarity. In the present specification, the expression ‘and/or’ is used to mean including at least one of constituent elements that are placed before and after ‘and/or’. Throughout the present specification, the same constituent elements are given the same reference number.

Terms used in the present specification are for describing the embodiments and are not intended to limit the present disclosure. In the present specification, singular forms also include plural forms unless specifically stated otherwise in a phrase. The terms “comprise” and/or “comprising” used in the specification should be construed to mean “including a constituent element, a step, an operation, or an element is mentioned, without excluding the presence or addition of one or more other constituent elements, steps, operations, or elements, respectively.”

The present disclosure will be described in more detail with reference to the drawings below. At this point, in order to provide spatial context, XYZ orthogonal coordinates were marked on the drawing of the semiconductor device structure.

The field effect transistor according to the present disclosure is a gate-all-around field effect transistor, more preferably a nanosheet gate-all-around field effect transistor (hereinafter referred to as ‘GAAFET’).

The GAAFET according to the present disclosure is a technology that can simultaneously solve problems of leakage current generated at the part under the channels and obstruction of heat release through the substrate.

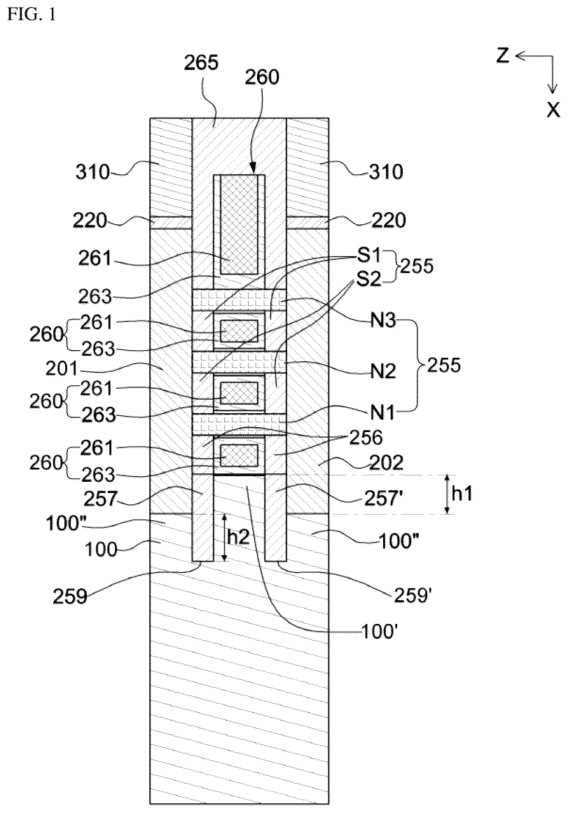

FIG. 1 is a cross-sectional view showing a GAAFET according to one embodiment of the present disclosure.

Referring to FIG. 1, the GAAFET according to the present disclosure includes a source region 201/a drain region 202 formed to be spaced apart from each other on the top of the substrate 100 from the bottom, a series of gate stacks 260 between the source region 201 and the drain region 202, and a series of channels N1, N2, N3, and 230 extending under the gate stacks 260 between the source region 201 and the drain region 202.

Further, the GAAFET according to the present disclosure includes an outer spacer 265 formed on top and side surfaces of the uppermost gate stack 260, inner spacers S1, S2, 255, and 256 connected to the outer spacer 265 and formed between the source region 201/drain region 202 and the gate stacks 260, and trench inner spacers 257 and 257′ vertically connected to the lowermost inner spacer 256 and positioned inside the grooves 259 and 259′ formed in the substrate 100.

Hereinafter, each component will be described in detail. The substrate 100 is not particularly limited in its kind in the present disclosure, and may be a substrate 100 typically used in this field. Representatively, it may be Si, SiGe, Ge, Sn (tin), or Group 3-5 compounds capable of performing a top-down process. At this point, the Group 3-5 compounds may be, for example, aluminum phosphide (AlP), gallium phosphide (GaP), indium phosphide (InP), aluminum arsenide (AlAs), gallium arsenide (GaAs), indium arsenide (InAs), aluminum antimonide (AlSb), gallium antimonide (GaSb), or indium antimonide (InSb).

The substrate 100 rarely has doped impurities, or may be doped with one or more n-type impurities selected from P, As, and Sb; or one or more p-type impurities selected from B, BF₂, Al, and Ga. The impurities introduced into the substrate 100 are different depending on the device type (NMOS or PMOS), and may be p-type in case of NMOS or n-type in case of PMOS.

A first groove 259 and a second groove 259′ having a trench structure are formed in the substrate 100. Although it will be described in detail below, trench inner spacers 257 and 257′ (hereinafter referred to as ‘TIS’) is positioned inside the first groove 259 and the second groove 259′.

Further, the substrate 100′ between the first groove 259 and the second groove 259′ of the substrate 100 may have the same thickness as other portion 100″, that is, the substrate 100″ which is located below the source region 201/drain region 202, but it may have a thickness different from that. Specifically, the substrate 100′ between the first groove 259 and the second groove 259′ is thicker than the substrate 100″ positioned below the source region 201/drain region 202, and thus, it is formed to protrude.

At this point, the thickness difference h1 between the substrate 100′ between the first groove 259 and the second groove 259′ and the substrate of the other portion 100″ may be a difference T_{SD} according to the over-etched S/D recess depth, and may be, for example, 0 to 200 nm, 0 to 100 nm, 0 to 50 nm, 0 to 30 nm, 0 to 20 nm, more than 0 and not more than 20 nm, or more than 0 nm and not more than 10 nm, but is not limited thereto.

Further, the width of the first groove 259 or the second groove 259′ formed on the substrate 100 is not particularly limited, but may be, for example, more than 0 and not more than 100 nm, 1 to 50 nm, 1 to 30 nm, 1 to 20 nm, 1 to 10 nm, 2 to 9 nm, or 3 to 8 nm. In addition, the widths of the first groove 259 and the second groove 259′ may be the same as or different from each other.

Further, the height of the first groove 259 or the second groove 259′ in the vertical direction is not particularly limited, but may be, for example, more than 0 and not more than 300 nm, more than 0 and not more than 200 nm, more than 0 and not more than 100 nm, 1 to 80 nm, 1 to 70 nm, 1 to 60 nm, 1 to 50 nm, 1 to 40 nm, 1 to 30 nm, 1 to 20 nm, 1 to 10 nm, or 2 to 10 nm, but is not limited thereto. In addition, the heights of the first groove 259 and the second groove 259′ in the vertical direction may be the same as or different from each other. However, the height of the first groove 259 or the second groove 259′ may be the length h2 in the vertical direction from the bottom surface of the first groove 259 and the second groove 259′ to the top surface of the substrate 100″ located below the source region 201/drain region 202.

A series of gate stacks 260 are positioned on the substrate 100.

Each gate stack 260 may be a replacement metal gate. The replacement metal gate includes a gate electrode 261 and a gate dielectric 263 (i.e., a gate dielectric layer or a stack of gate dielectric layers) such as a high-dielectric gate oxide film and an interfacial layer. The gate stacks 260 have a gate-all-around (GAA) structure surrounding the circumference of the channel 230 regions.

The gate electrode 261 includes a work function metal such as W, Al, Cr, or Ni, and a metal barrier of Ti, TiN, or Al may be formed if necessary. The gate dielectric 263 may be SiO₂, Al₂O₃, HfO₂, ZrO₂, Si₃N₄, perovskite oxide, or the like. According to one embodiment of the present disclosure, the gate stacks 260 may have a structure in which a gate dielectric/a metal barrier/a work function metal are sequentially stacked.

The channels N1, N2, N3, and 230 may be formed of one or more selected from GaN, Si, Ge, SiGe, GaAS, W, Co, Pt, ZnO, and In₂O_{3.}

The channels 230 may be a plurality of nano sheet channels. In addition to this structure, they may be in the form of a known nano wire, nano fiber, nano rod, or nano ribbon, and may be made of a P-type or N-type semiconductor material. The number of layers of the channels 230 is not limited to three, but may be as small as one layer (each layer), and in some embodiments, each channel layer is formed of 2 to 10 layers. The driving current of the GAAFET device may be adjusted by adjusting the number of stacked layers.

In the case of a nanosheet GAAFET structure, the channels 230 may be active nanosheet channel layers N1, N2, and N3, and although not shown, a sacrificial nanosheet layer is formed between these active nanosheet channel layers. The sacrificial nanosheet layer may be formed of a sacrificial semiconductor material such as Si or SiGe having a Ge concentration different from that of an SiGe material forming the active nanosheet channel layer. However, at this point, the lowermost layer N3 of the active nanosheet channel layer contains an Si material. Preferably, the active nanosheet channel layer/sacrificial nanosheet layer has a structure in which Si/SiGe is stacked, and at this point, the sacrificial nanosheet layer is located in a layer close to the substrate 100, and the material thereof may be SiGe. The source region 201/drain region 202 are formed by epitaxially growing a semiconductor material (e.g., epitaxial Si material or SiGe material) on the exposed sidewall surfaces of the channels N1, N2, N3, and 230 and the exposed top surface of the substrate 100. Specifically, the source region 201/drain region 202 are grown on the substrate 100 and along the side surface of the channels 230 vertically (in the Z-axis direction) and horizontally (in the Y-axis direction) and formed to protrude.

A silicide 220 and a contact metal layer 310 are formed on the top of the source region 201/drain region 202.

The silicide 220 has a wrap-around-contact structure surrounding the source region 201/drain region 202.

The silicide 220 may preferably include a metal silicide material, may be used by bonding a metal, usually used with a semiconductor, and Si, and may be, for example, a silicide material including Ni, Co, W, Ta, Ti, Pt, Er, Mo, Pd, or alloys thereof. More specifically, the metal silicide may include NiSi₂, CoSi₂, WSi₂, TaSi₂, TiSi₂, PTIS₂, ErSi₂, MoSi₂, PdSi₂, or combinations thereof, but is not particularly limited thereto in the present disclosure. In addition, the silicide 220 may be a single layer or multiple layers containing the above-mentioned materials.

Further, a contact metal layer 310 filled with a metal material such as Co, W, or Ru is formed in order to electrically connect the source region 201/drain region 202.

The GAAFET with such a structure includes a plurality of spacers for various purposes such as insulation between the respective layers.

Specifically, an outer spacer 265 is included on the uppermost channel layer N3 and on both surfaces of the uppermost gate stack 260.

A series of first inner spacers S1, S2, and 255 are formed between two channel layers formed to be vertically neighboring to each other and between the source region 201/drain region 202 and the gate stacks 260.

Second inner spacers 256 are formed on the bottom of the lowermost channel N1 and between the source region 201/drain region 202 and the lowermost gate stack 260.

An insulating material such as SiO₂, Al₂O₃, HfO₂, ZrO₂, Si₃N₄, or perovskite oxide may be used for the outer spacer 265 and the first and second inner spacers 255 and 256. Materials of the outer spacer 265 and the first and second inner spacers 255 and 256 may be the same as or different from each other.

Particularly, TISs 257 and 257′ vertically connected to the second inner spacers 256 and vertically extended to the inside of the first groove 259 and the second groove 259′ of the trench structure formed in the substrate 100 is included on the bottom of the second inner spacers 256. The material of the TISs 257 and 257′ may be the same as or different from that of the first inner spacer 255 or the second inner spacer 256, and may include the aforementioned insulating materials.

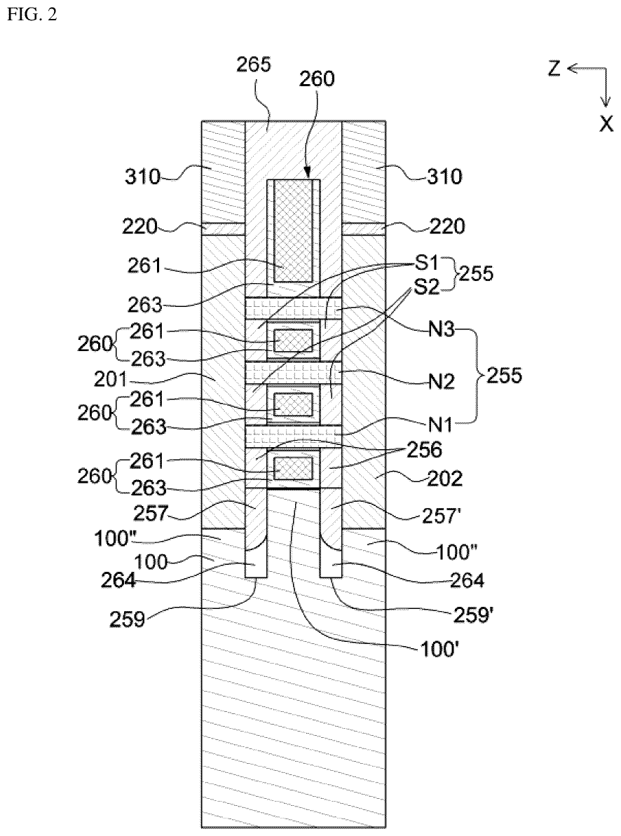

FIG. 2 is a cross-sectional view showing a GAAFET according to another embodiment of the present disclosure, and a remaining part 264 vertically extending from the bottom surfaces of the TISs 257 and 257′ to the bottom surfaces of the first and second grooves 259 and 259′ is included at lower end portions of the first and second grooves 259 and 259′ of the trench structure of the substrate 100. As will be described below, the remaining part 264 is a part in which a portion of the sacrificial layer remains, and may include Si, Ge, or a combination thereof, but is not limited thereto.

In FIG. 2, when the remaining part 264 remains as described above, the shape of the bottom surfaces of the TISs 257 and 257′ is not particularly limited, and may be a fan shape as in the illustrated embodiment, but various shapes such as a cross-sectional shape, an oblique line shape, or a meandering shape may be included without limitation.

The TISs 257 and 257′ according to the present disclosure has a structure that cannot be seen in conventional GAAFET devices, and provides various advantages regardless of whether or not the remaining part 264 is present on the bottom thereof.

In the present disclosure, diffusion of impurities in the source region/drain region into the substrate is prevented through the structure of the TISs 257 and 257′, and through this, leakage current generation at the channel bottoms is suppressed. In addition, according to the present disclosure, robustness of source region/drain region recess process variables is ensured in the GAAFET device through the structures of the TISs 257 and 257′.

FIG. 5 is a diagram for explaining source region/drain region recesses. Referring to FIG. 5, an etching process is performed in order to form a source region/a drain region, and the actual etching process does not occur ideally, but an unintentional over-etching phenomenon occurs frequently due to process variation. At this point, T_{SD} of FIG. 5 means an over-etched S/D recess depth.

As the T_{SD} becomes deeper, diffusion of source region/drain region impurities to the part under the channels occurs more seriously, and as the T_{SD} becomes deeper, the source region/drain region impurities are more widely diffused to the part under the channels. The diffusion of the impurities causes generation of leakage current as mentioned above. However, such diffusion of impurities and suppression of leakage current may be solved through the structure of the TISs 257 and 257′, and particularly, the same effect may be maintained in the present disclosure regardless of the depth of the TSD through the formation of the TISs 257 and 257′.

As a result of conducting a simulation experiment according to the degree of diffusion of impurities according to the depth of the TSD in the GAAFET device including the TISs 257 and 257′ according to the present disclosure, even if the T_{SD} was deepened, the diffusion of the source region/drain region impurities to the part under the channels was suppressed, and the generation of leakage current due to this diffusion could be suppressed or minimized.

Through these results, it can be seen that the robustness of the source region/drain region recess process variables can be ensured with the GAAFET device including the TISs 257 and 257′ according to the present disclosure.

The above-described robustness may be achieved when Equation 1 below is satisfied.

$${H}_{TIS} = {T}_{SD} + {L}_{IS} \qquad [ Equation 1 ]$$

where H_{TIS}, as a height of the TIS, is a vertical length of the TIS with respect to the TIS sidewalls in contact with the source region/drain region, T_{SD} is an over-etched source region/drain region recess depth, and L_{IS} is a horizontal length of the second inner spacer, and is equal to a vertical length from the lowermost point in the vertical direction on the TIS sidewalls in contact with the source region/drain region to the top surface of the substrate located on the bottom of the source region/drain region.

Referring to Equation 1 above, as T_{SD} becomes deeper, more leakage current and parasitic capacitance occur, and the leakage current due to T_{SD} causes a serious increase in static power consumption and, in severe cases, the GAAFET device does not serve as a semiconductor device.

T_{SD} may be 0 to 200 nm, 0 to 100 nm, 0 to 50 nm, 0 to 30 nm, 0 to 20 nm, more than 0 nm and not more than 20 nm, or more than 0 nm and not more than 10 nm.

Further, L_{IS} may be more than 0 nm and not more than 100 nm, 1 to 50 nm, 1 to 30 nm, 1 to 20 nm, 1 to 10 nm, 2 to 9 nm, or 3 to 8 nm.

As a result, H_{TIS} may be more than 0 nm and not more than 300 nm, more than 0 nm and not more than 200 nm, more than 0 nm and not more than 100 nm, 1 to 80 nm, 1 to 70 nm, 1 to 60 nm, 1 to 50 nm, 1 to 40 nm, 1 to 30 nm, 1 to 20 nm, 1 to 10 nm, or 2 to 10 nm.

Conventionally, although a technique for preventing leakage current under the channels has been proposed as a technique of forming only a punch through stopper under the source region/drain region, the robustness of the source region/drain region recess process variables, which may be achieved when Equation 1 is satisfied, has not yet been proposed.

Further, in the present disclosure, it is possible to smoothly release heat through the substrate in the GAAFET device through the structure of the TISs 257 and 257′, and particularly, the GAAFET device has an excellent heat release effect compared to the device of the BOX Scheme structure.

The conventional suggested technique of depositing a dielectric layer on the parts under the source region/drain region for preventing leakage current (BOX scheme) has been able to obtain an effect of preventing the leakage current to some extent. However, when SiO₂ or Si₃N₄, which is the material of the dielectric layer, is deposited, there is a problem in that heat generated from the device cannot be released through the Si substrate due to thermal conductivity of an insulator lower than that of Si, which is the substrate material. Normally, Si has a thermal conductivity of 150 to 170 W/m·K, SiO₂ has a thermal conductivity range of 1.3 to 1.5 W/m·K, and Si₃N₄ has a thermal conductivity range of 10 to 43 W/m·K.

As a result of conducting a simulation experiment of heat release through the substrate in the GAAFET device including the TISs 257 and 257′ according to the present disclosure, heat release was performed smoothly in the case of the GAAFET device in which over-etching did not occur, but heat release was not performed smoothly in the case of the BOX scheme structure in which a dielectric layer was formed in order to prevent leakage current. However, since heat release was easy in the case of the GAAFET device in which the TIS 257 according to the present disclosure was formed, deterioration of device performance could be prevented.

The GAAFET device having the TISs 257 and 257′ follows a conventional method for manufacturing a GAAFET device, but a trench patterning process for forming the TISs 257 and 257′ is additionally performed. Since the trench patterning process is performed at the beginning of the process, the consistency of patterning can be precisely controlled so that there is an advantage in that the technology application possibility and completeness are very high. In addition, since other processes can utilize existing ones as they are, the present technology has high applicability.

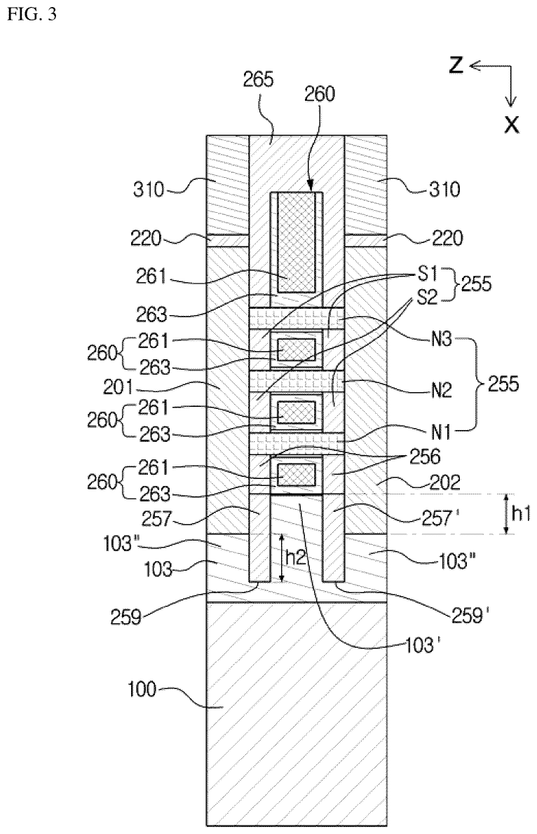

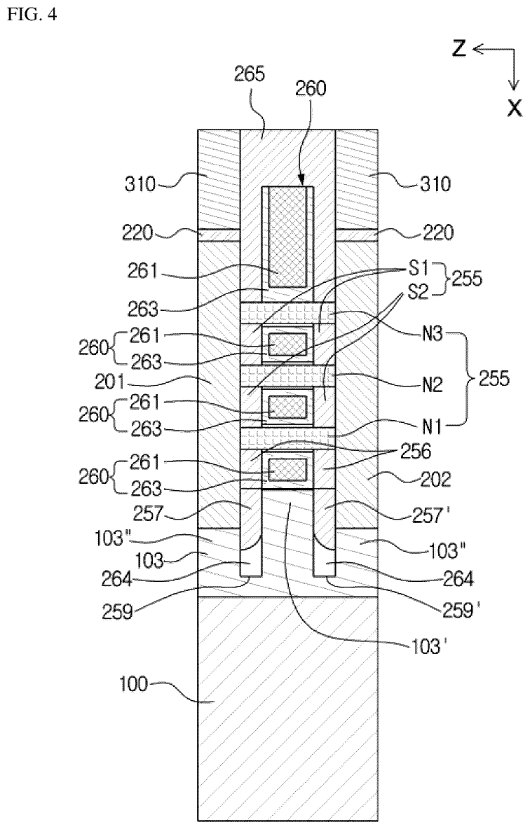

FIGS. 3 and 4 are cross-sectional views showing a GAAFET according to another embodiment of the present disclosure, a punch through stopper 103 (hereinafter referred to as ‘PTS’) is included on a substrate 100, and a source region 201/a drain region 202, a series of gate stacks 260 between the source region 201/drain region 202, and a series of channels N1, N2, N3, and 230 extending under the gate stacks 260 between the source region 201 and the drain region 202.

A first groove 259 and a second groove 259′ of a trench structure are formed in the PTS 103, and the PTS 103′ between the first groove 259 and the second groove 259′ of the trench structure may have a thickness that is the same as or different from that of the other part 103″, that is, the PTS 103″ located on the bottom of the source region 201/drain region 202. In detail, the PTS 103′ between the first groove 259 and the second groove 259′ is thicker than the PTS 103″ positioned on the bottom of the source region 201/drain region 202 so that it is formed to protrude.

At this point, the thickness difference h1 between the PTS 103′ between the first groove 259 and the second groove 259′ and the PTS of the other part 103″ may be a difference according to over-etched S/D recess depth, that is, T_{SD}, and may be, for example, 0 to 200 nm, 0 to 100 nm, 0 to 50 nm, 0 to 30 nm, 0 to 20 nm, more than 0 and not more than 20 nm, or more than 0 nm and not more than 10 nm, but is not limited thereto.

Hereinafter, a method for manufacturing a GAAFET having the TIS according to the present disclosure will be described step by step.

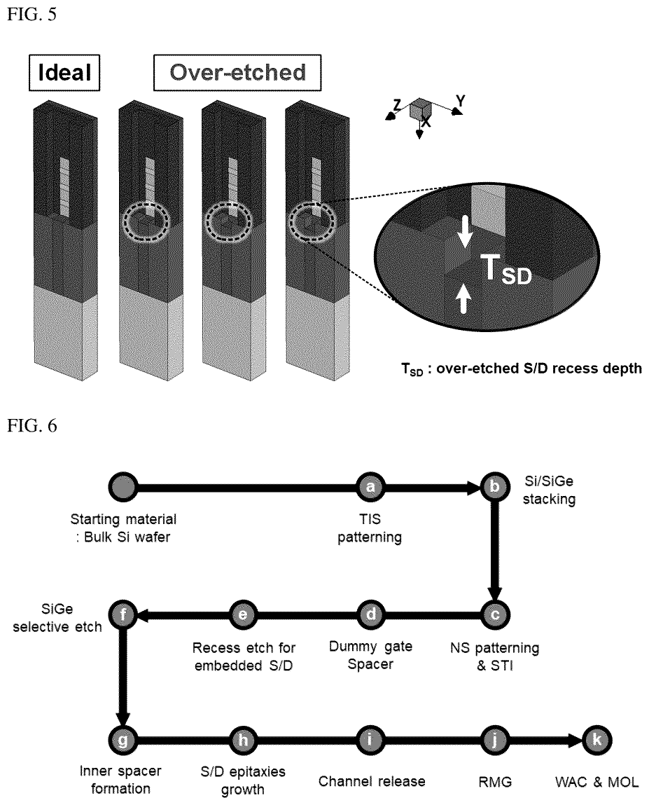

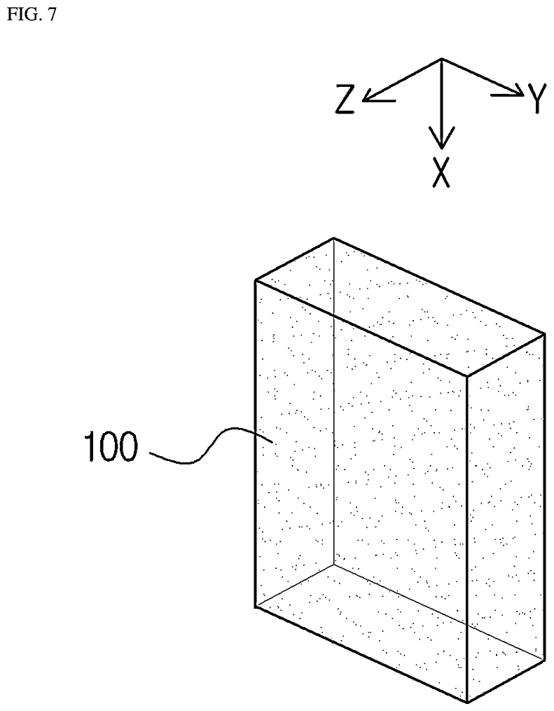

A GAAFET according to one embodiment of the present disclosure may be manufactured by the steps described in FIG. 6. Specifically, a method for manufacturing the GAAFET according to one embodiment of the present disclosure is carried out by including steps of:
(a) patterning the top of one side of the substrate to have a trench structure;
(b) forming a plurality of channels and sacrificial layers alternately arranged on the substrate;
(c) forming a shallow trench isolation (STI) region and patterning the channels and sacrificial layers;
(d) forming a dummy gate;
(e) vertically etching the channels and the sacrificial layers in order to form a source region/a drain region;
(f) selectively etching portions of the sacrificial layers in contact with the channels;
(g) depositing an insulating material on the trench structure in the substrate and on an etching region of the selectively etched sacrificial layers, thereby forming first and second inner spacers, and trench inner spacer that are connected to the second inner spacer and vertically extended up to the inside of the trench structured groove formed in the substrate;
(h) forming a source region/a drain region by a selective epitaxial growth process;
(i) releasing the channels;
(j) forming a replacement metal gate; and
(k) performing WAC and MOL processes.

Hereinafter, each step will be described with reference to the drawings.

At this point, the formation of each layer includes a deposition process, a lithography process, and an etching process, and each layer is formed by another appropriate processes in addition to them or combinations thereof. Unless otherwise specified, each layer is subjected to a deposition process, followed by a lithography process and an etching process in this order.

The deposition process includes CVD, physical vapor deposition (PVD), atomic layer deposition (ALD), high density plasma chemical vapor deposition (HDPCVD), metal organic chemical vapor deposition (MOCVD), remote plasma chemical vapor deposition (RPCVD), plasma-enhanced chemical vapor deposition (PECVD), low pressure chemical vapor deposition (LPCVD), atomic layer chemical vapor deposition (ALCVD), atmospheric pressure chemical vapor deposition (APCVD), evaporation deposition, plating, other suitable methods, or combinations thereof.

The lithography process may include any one process of electron beam lithography, nanoimprint, ion beam lithography, X-ray lithography, extreme ultraviolet lithography, photolithography (stepper, scanner, contact aligner, etc.), maskless lithography, or randomly scattered nanoparticles, and is not particularly limited in the present disclosure. The photolithography process among them includes resist coating (e.g., spin on coating), soft baking, mask alignment, exposure, post-exposure baking, resist development, rinsing, drying (e.g., hard baking), other suitable processes, or combinations thereof.

The etching process includes a dry etching process, a wet etching process, another etching process, or combinations thereof. At this point, metals such as Cr, Ni, and Al, or photoresist in addition to insulating films such as SiO₂ and SiNₓ may be used as an etching mask material.

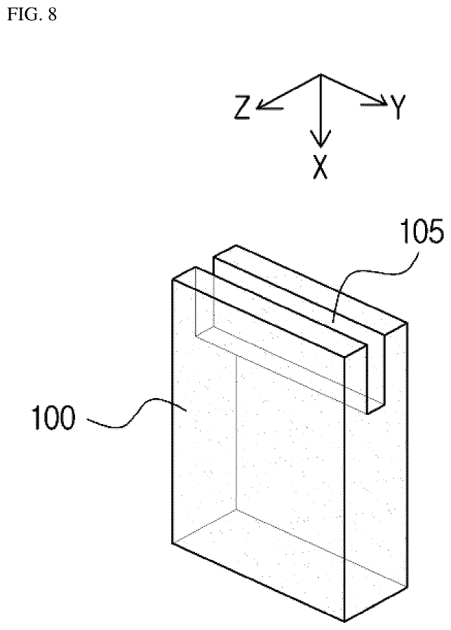

FIGS. 7 to 19 are views showing a manufacturing process of the GAAFET device of FIG. 2 according to one embodiment of the present disclosure. For understanding, the device is explained with the X-Z-Y coordinates and the Z-X cross sectional view. The GAAFET device in these drawings has a symmetrical structure in the z direction, and for convenience, only one side surface of the symmetrical structure is shown.

A TIS forming region 105 having a trench structure is formed by performing patterning on the top of one side of the substrate 100 (FIG. 8).

As shown in FIG. 8, the TIS forming region 105 may be a groove having the trench structure, and at this point, the TIS forming region 105 is formed, taking into consideration H_{TIS} that is the height of the TIS that is limited by Equation 1.

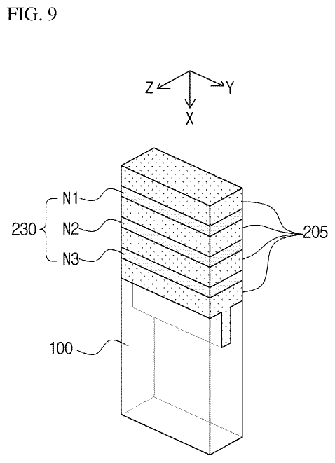

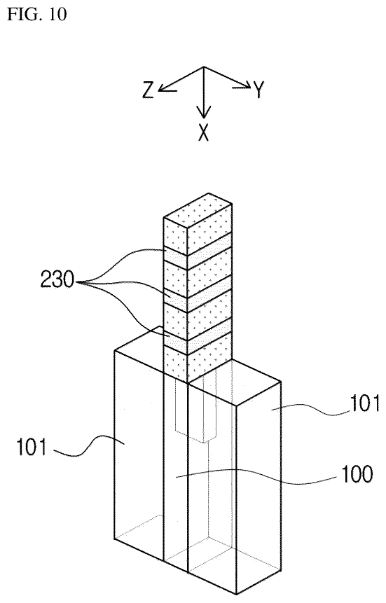

Next, a plurality of channels N1, N2, N3, and 230 and sacrificial layers 205 alternately arranged on the substrate 100 are formed (FIG. 9).

In a nanosheet FET shown in FIG. 9, the channels 230 may be active nanosheet channel layers (Si NS), and the sacrificial layers 205 may be sacrificial nanosheet layers (SiGe NS). The sacrificial nanosheet layers may be formed of a sacrificial semiconductor material such as Si or SiGe having a Ge concentration different from that of an SiGe material forming the active nanosheet channel layers. According to one embodiment, the active nanosheet channel layers are Si, the sacrificial nanosheet layers are SiGe, and the lowermost sacrificial nanosheet layer contains an SiGe material. That is, in the case of FIG. 9, the nanosheet FET is composed of layers of SiGe/Si/SiGe/Si/SiGe/Si/SiGe from the bottom.

In particular, the sacrificial layer 205 (SiGe NS) located at the lowermost layer is filled up to the TIS forming region 105 unlike the conventional art, and as shown in FIG. 9, shows a structure in which a portion of the sacrificial layer 205 of the lowermost layer has a T-shape extending structure in the vertical direction.

Next, the STI region 101 is formed while patterning the channels 230 and the sacrificial layers 205 (FIG. 10).

Side surfaces of the channels 230 and the sacrificial layers 205 are vertically etched to form nanostructures.

The isolation insulating layer, that is referred to as a shallow trench isolation (STI) region 101, may be formed of a suitable dielectric material selected from low-k dielectrics such as silicon oxide, silicon nitride, silicon oxynitride, fluorine-doped silicate glass (FSG), and carbon-doped oxide, ultra low-k dielectrics such as porous carbon-doped silicon dioxide, polymers such as polyimide, combinations thereof, and the like. If necessary, it may be formed of a silicon oxide material through a thermal oxidation process of the substrate 100.

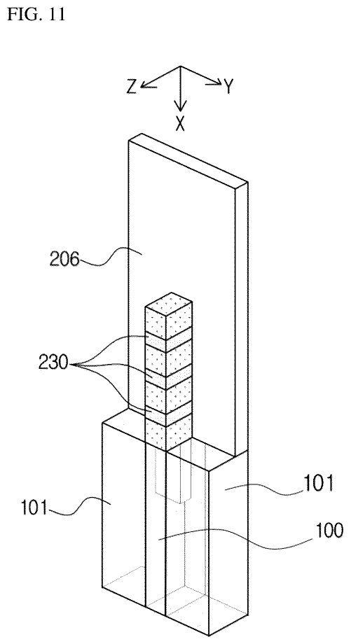

Next, a dummy gate 206 is formed to surround the channels 230 and the sacrificial layers 205 (FIG. 11). The dummy gate 206 may be a polysilicon gate, and is formed through a patterning process after deposition.

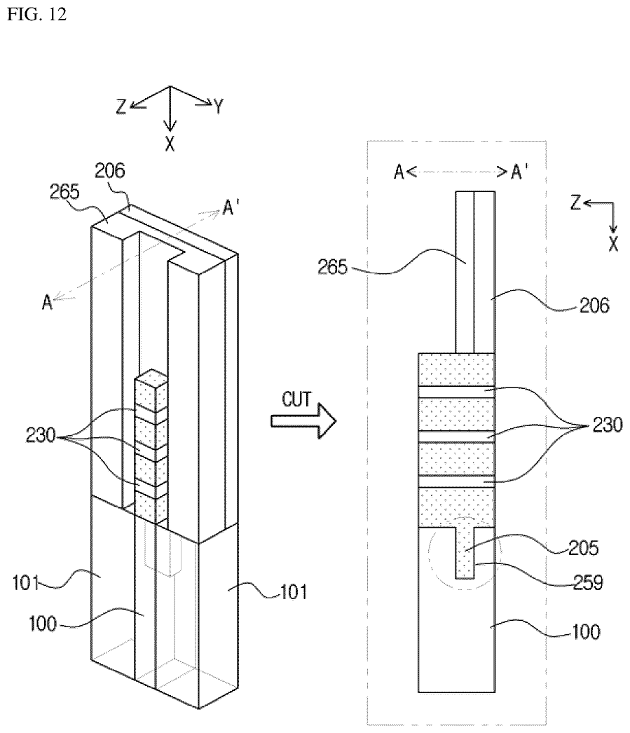

Next, an outer spacer 265 is formed (FIG. 12).

The outer spacer 265 is formed through a patterning process after performing deposition using a material having insulating properties so that the channels 230 and the sacrificial layers 205 are surrounded. As seen from a cross-sectional view taken along line A-A′ on FIG. 12, the outer spacer 265 is formed on the channels 230 and the sacrificial layers 205 in a manner that is spaced a predetermined distance apart vertically from the bottom. At this point, a portion of the lower end of the sacrificial layer 205 in contact with the PTS 103 shows a structure extending in a vertical direction into the PTS 103 like a ‘T’ shape.

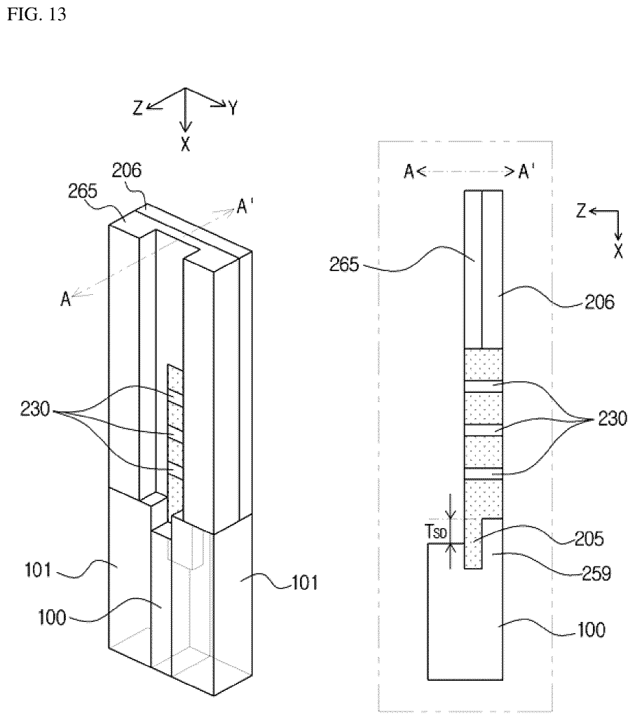

Next, the channels 230 and the sacrificial layers 205 are vertically etched in order to form a source region/a drain region (FIG. 13).

In this vertical etching, additional etching corresponding to T_{SD} further occurs on the substrate 100 region for forming a source region/a drain region. As a result, as shown in FIG. 13, a structure in which the substrate 100 region and the lowermost sacrificial layer 205 are engaged with each other is formed.

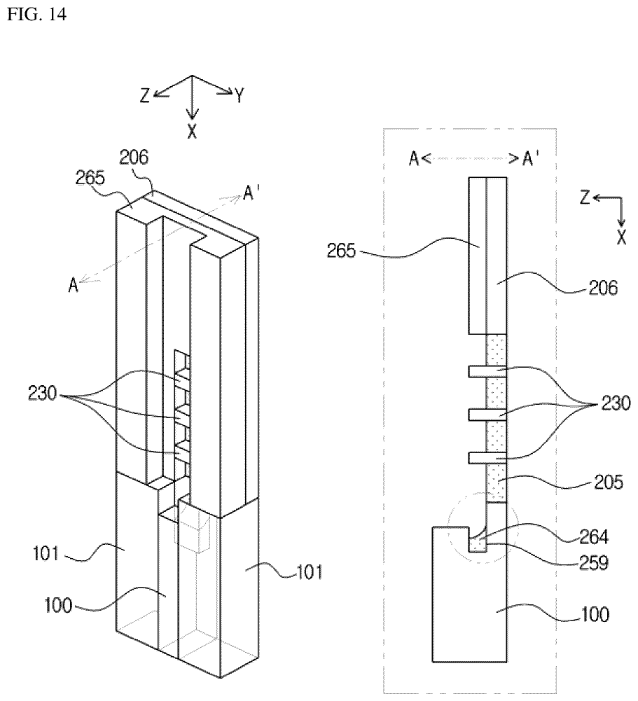

Next, a selective etching process of the sacrificial layers 205 in contact with the channels 230 is performed (FIG. 14).

In the selective etching process, only the sacrificial layers 205 are selectively etched using a difference in etching rate according to a material composition ratio or material difference between the channels 230 and the sacrificial layers 205. In order to remove performance deterioration factors such as surface state density generated on the etching surface during the etching process, a process of removing the film through dry etching or wet etching after growing a film by using a thermal oxidation process may be added.

When the sacrificial layers 205 are selectively etched, etching is performed up to the inside of the trench structured groove of the substrate 100. At this point, a remaining part 264 in which a portion of the sacrificial layer 205 remains may be present inside the trench structured groove indicated by a circle in the right side of FIG. 14, particularly in the lower end portion (e.g., SiGe residue). If necessary, the remaining part 264 may be completely removed through additional etching or selective etching.

At this point, the trench structured groove of the substrate 100 provides a substantial space for TIS formation.

Particularly, referring to FIG. 14, after the selective etching process, the substrate 100 has a height difference between a region for forming a source region/a drain region and a region in contact with the sacrificial layers 205. However, although not shown in the drawing, the height difference may not exist between the region for forming the source region/drain region and the region in contact with the sacrificial layers 205 on the substrate 100 unless over-etching occurs during etching for forming the source region/drain region.

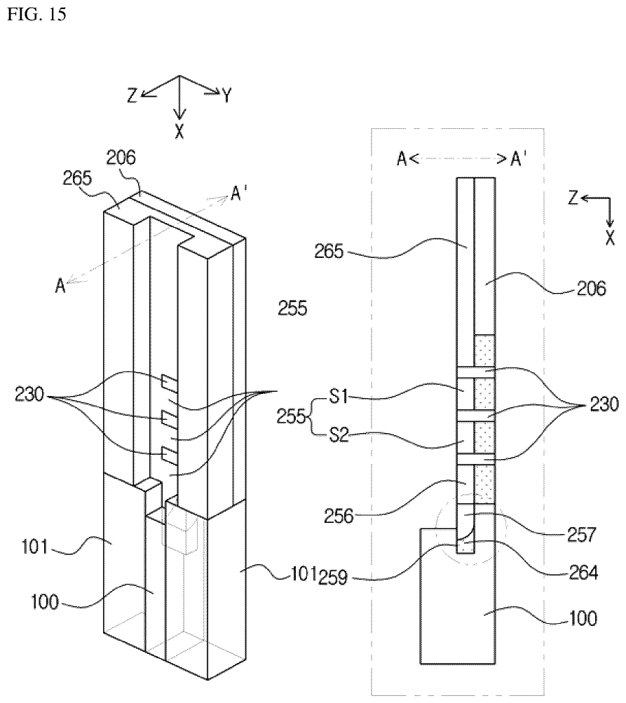

Next, the first and second inner spacers 255 and 256, and the TISs 257 that are connected to the first and second inner spacers 255 and 256 and vertically extended up to the inside of the trench structured groove formed in the substrate are formed by depositing an insulating material on the trench structure in the substrate 100 and on an etching region of the selectively etched sacrificial layer 205 (FIG. 15).

Referring to the region indicated by a circle in the right side of FIG. 15, the substantial region of the TIS 257 means a region vertically extending from the bottom surface of the second inner spacer 256 to the bottom of the trench structured groove, and to the top or the top surface of the remaining part 264 when the remaining part 264 remains on the bottom of the groove. Although not shown in the drawing, when the remaining part 264 does not remain on the bottom of the groove, the TIS 257 may vertically extend from the bottom surface of the second inner spacer 256 to the bottom surface of the trench structured groove.

At this point, the TIS 257 may be formed so that it has a height represented by Equation 1 below.

$${H}_{TIS} = {T}_{SD} + {L}_{IS} \qquad [ Equation 1 ]$$

where H_{TIS}, as a height of the TIS, is a vertical length of the TIS with respect to the TIS sidewalls in contact with the source region/drain region, T_{SD} is an over-etched source region/drain region recess depth, and L_{IS} is a horizontal length of the second inner spacer, and is equal to a vertical length from the lowermost point in the vertical direction on the TIS sidewalls in contact with the source region/drain region to the top surface of the substrate located on the bottom of the source region/drain region.

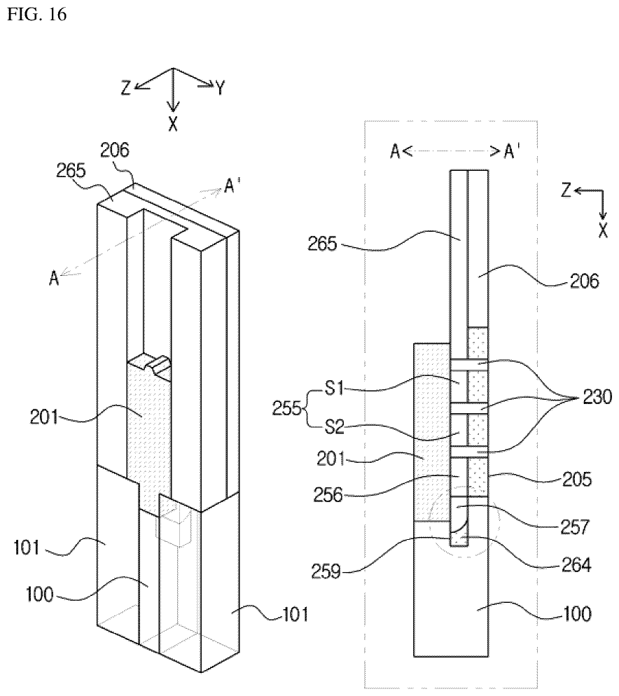

Next, a source region 201/a drain region 202 are formed by a selective epitaxial growth process (FIG. 16). At this point, only one side is shown in the drawing, and thus only the source 201 region is shown, but the drain 202 is formed on the other side.

Selective epitaxial growth is performed by epitaxially growing a semiconductor material (e.g., epitaxial Si material or SiGe material) on the exposed sidewall surfaces of the channels N1, N2, N3, and 230. For the selective epitaxial growth process, solid phase epitaxy (SPE), vapor phase epitaxy (VPE), and liquid phase epitaxy (LPE) methods may be used. According to one embodiment, an epitaxial layer may be formed by epitaxial growth (e.g., hetero-epitaxy) using a chemical vapor deposition (CVD), reduced pressure chemical vapor deposition (RPCVD), ultrahigh vacuum chemical vapor deposition (UHCVD), or molecular beam epitaxy (MBE) method.

The source region 201/drain region 202 are formed to protrude by being grown vertically (in the Z-axis direction) and horizontally (in the Y-axis direction) along the side surfaces of the channels 230 by the selective epitaxial growth process.

Through the selective epitaxial growth process, n-type or p-type impurities are implanted into the source region 201/drain region 202 without a separate ion implantation process.

At this point, the impurity type is different depending on the device type (NMOS or PMOS), and it may be n-type in case of NMOS or p-type in case of PMOS. For example, the source region 201/drain region 202 may be doped with one or more n-type impurities selected from P, As, and Sb; or one or more p-type impurities selected from B, BF₂, Al, and Ga.

If necessary, in order to increase the stress effect of the channels 230, Si, SiGe, Ge, Sn(tin), and Group 3-5 compounds in addition to the impurities may be mixed and used. At this point, the Group 3-5 compounds may include, for example, aluminum phosphide (AIP), gallium phosphide (GaP), indium phosphide (InP), aluminum arsenide (AlAs), gallium arsenide (GaAs), indium arsenide (InAs), aluminum antimonide (AlSb), gallium antimonide (GaSb), and indium antimonide (InSb).

As illustrated in the right side of FIG. 16, the height of TIS, that is, Hₜᵢₛ, is involved in T_{SD}, as mentioned in Equation 1, and even if the T_{SD} variation occurs, diffusion of the impurities of the source region 201/drain region 202 into the part under the channels 230 is prevented.

Next, the step of releasing the channels is performed.

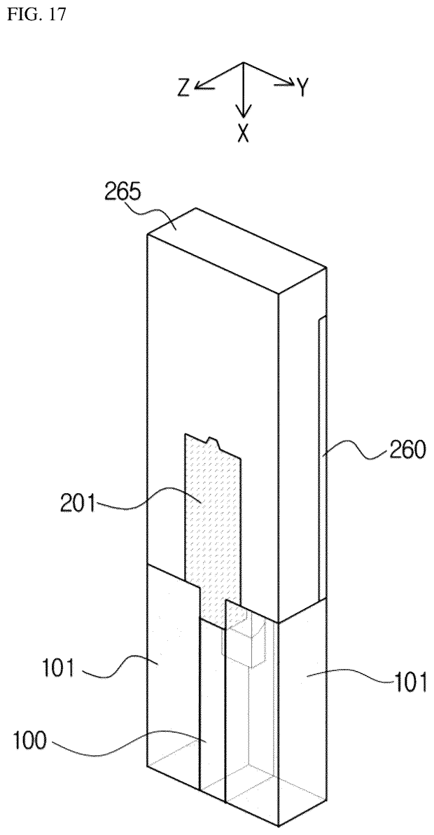

Next, a gate stack 260 is formed by performing a replacement metal gate (RMG) forming process (FIG. 17).

The gate stack 260 is formed by removing the existing dummy gate 206 and depositing a gate electrode 261 and a gate dielectric 263. As shown in FIG. 1, the gate stack 260 has a GAA structure that surrounds a top, a bottom and/or a lateral-side surface of the channel 230, that is, three-dimensionally surrounds the channel 230.

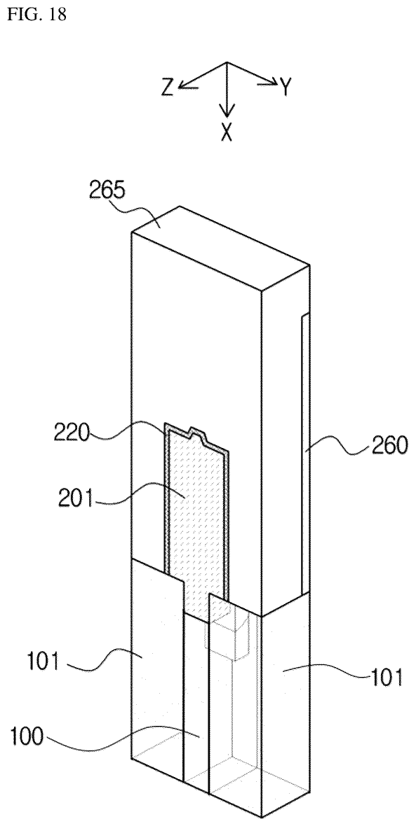

Next, a process of forming silicide 220 on the source region 201/drain region 202 is performed (FIG. 18).

The source region/drain region include a silicon or polysilicon material, and silicide is formed by implanting metal ions such as Ni, Co, W, Ta, Ti, Pt, Er, Mo, Pd, or alloys thereof thereinto. As a result, as shown in FIG. 18, silicide 220 is formed to surround the source region 201/drain region 202, and the contact opening region remains exposed.

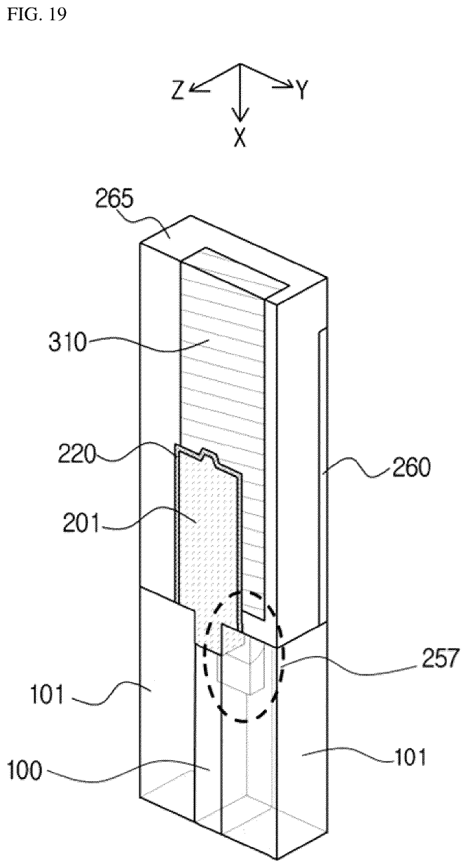

Next, the contact metal layer 310 is formed by performing a wrap around contact (WAC) and middle of line (MOL) processes for filling metal in the contact opening region (FIG. 19). Filling of the contact metal layer may be performed through a deposition process of a metal material such as Co, W, or Ru.

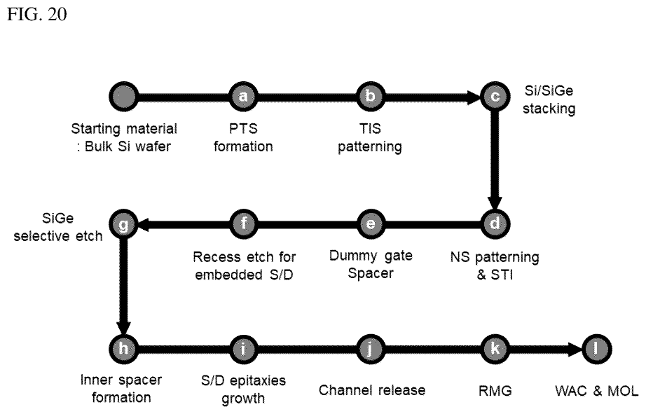

A GAAFET according to another embodiment of the present disclosure may be manufactured by the steps described in FIG. 20. Specifically, a method for manufacturing the GAAFET according to another embodiment of the present disclosure is carried out by including steps of:
(a) forming a punch through stopper (PTS) on a substrate;
(b) patterning the top of one side of the punch through stopper (PTS) to have a trench structure;
(c) forming a plurality of channels and sacrificial layers alternately arranged on the substrate;
(d) forming a shallow trench isolation (STI) region and patterning the channels and sacrificial layers;
(e) forming a dummy gate;
(f) vertically etching the channels and the sacrificial layers in order to form a source region/a drain region;
(g) selectively etching portions of the sacrificial layers in contact with the channels;
(h) depositing an insulating material on the trench structure in the substrate and on an etching region of the selectively etched sacrificial layers, thereby forming first and second inner spacers, and trench inner spacer that are connected to the second inner spacer and vertically extended up to the inside of the trench structured groove formed in the punch through stopper (PTS);
(i) forming a source region/a drain region by a selective epitaxial growth process;
(j) releasing the channels;
(k) forming a replacement metal gate; and
(l) performing WAC and MOL processes.

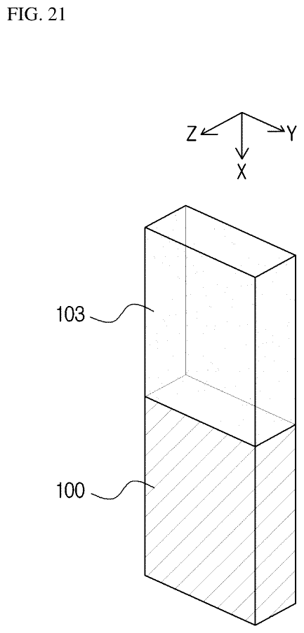

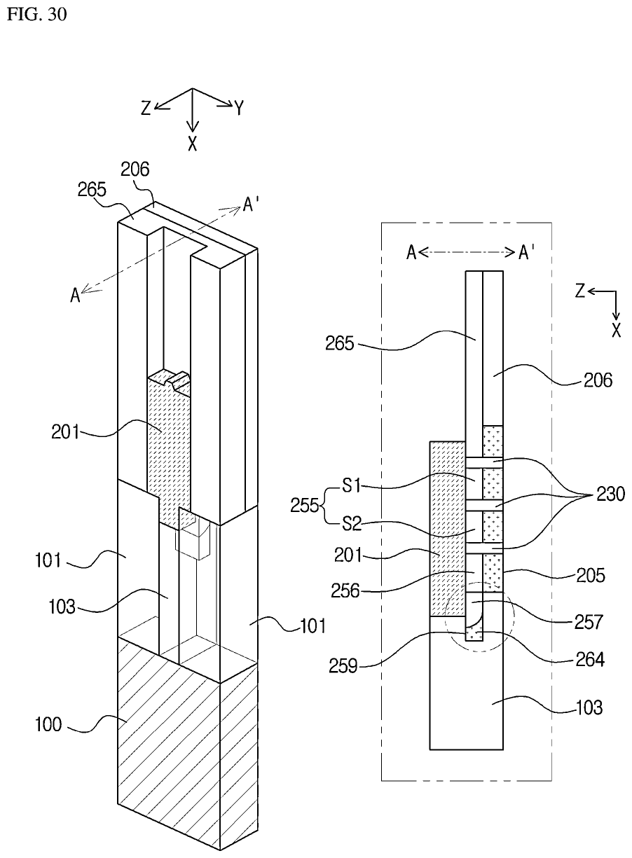

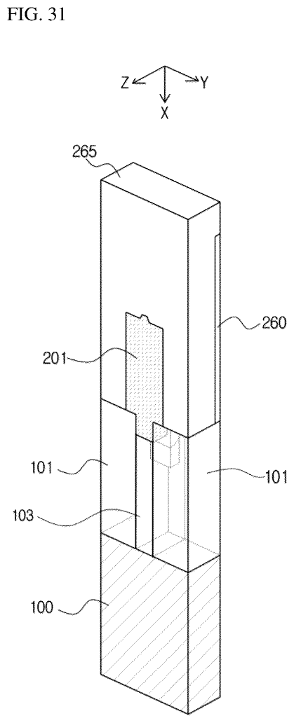

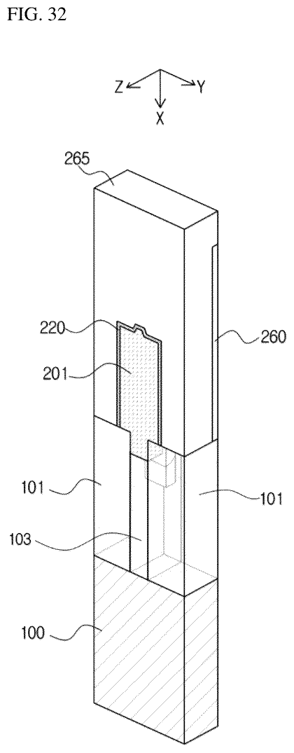

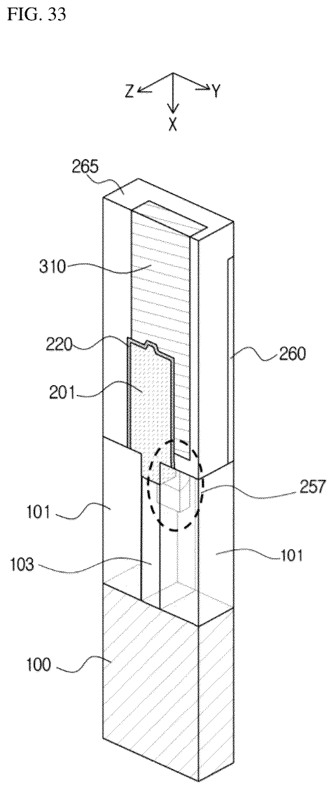

FIGS. 21 to 33 are views showing a manufacturing process of the GAAFET device of FIG. 4 according to another embodiment of the present disclosure. For understanding, the device is explained with the X-Z-Y coordinates and the Z-X cross sectional view. The GAAFET device in these drawings has a symmetrical structure in the z direction, and for convenience, only one side surface of the symmetrical structure is shown.

First, the PTS 103 is formed on the substrate 100 (FIG. 21).

In order to effectively block leakage current under the channels 230, the PTS 103 is formed by implanting impurities of a type opposite to that of the source region/drain region in a high concentration into a predetermined region under the channels and then performing heat treatment.

Since the impurity implantation and heat treatment processes have to be performed to form the PTS 103, the impurity implantation and heat treatment processes is performed immediately before performing the selective epitaxial growth process for forming the source region and the drain region, more preferably, immediately before performing a process of forming the shallow trench isolation (STI) region, in order for these processes not to damage a device or not to have a bad effect on the device.

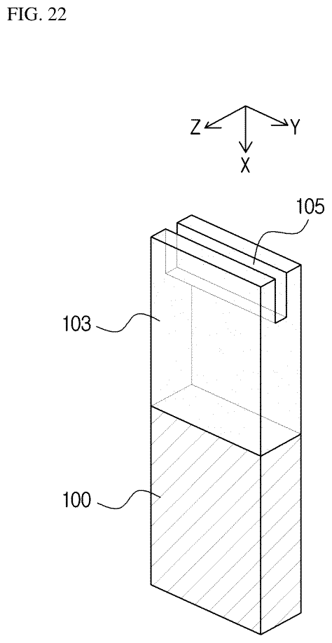

Next, a trench structured groove 105 which is the region for TIS forming is formed by patterning the top of the PTS 103 (FIG. 22). At this point, the TIS forming region 105 is formed, taking into consideration H_{TIS} that is the height of the TIS that is limited by Equation 1.

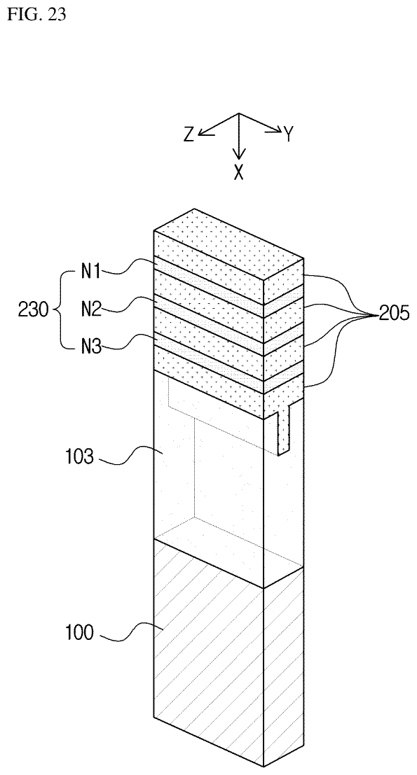

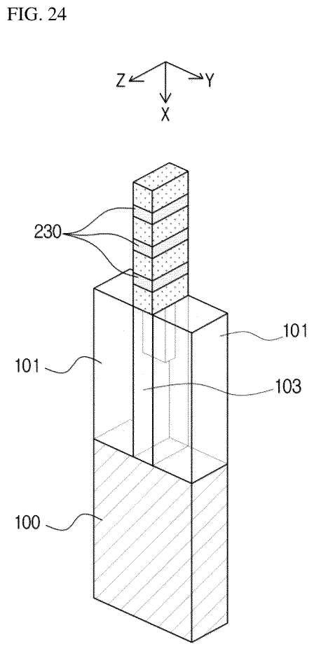

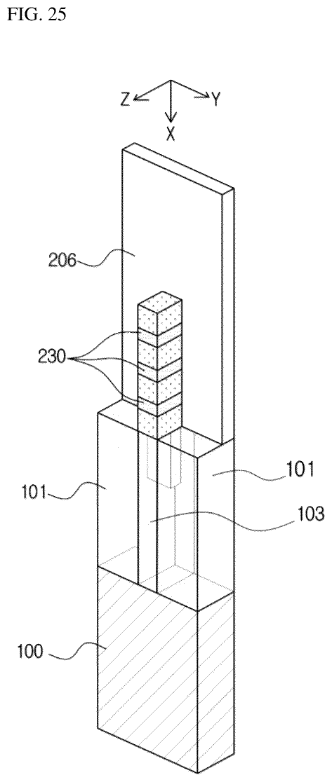

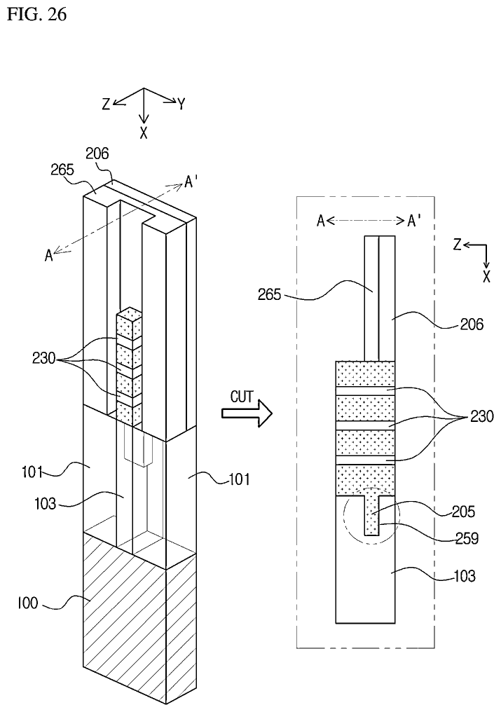

Next, a plurality of channels N1, N2, N3, and 230 and sacrificial layers 205 alternately arranged on the PTS 103 are formed (FIG. 23), and the channels 230 and the sacrificial layers 205 are patterned, and the STI region 101 is formed (FIG. 24). Thereafter, the dummy gate 206 is formed to surround the channels 230 and the sacrificial layers 205 (FIG. 25), and then the outer spacer 265 is formed (FIG. 26).

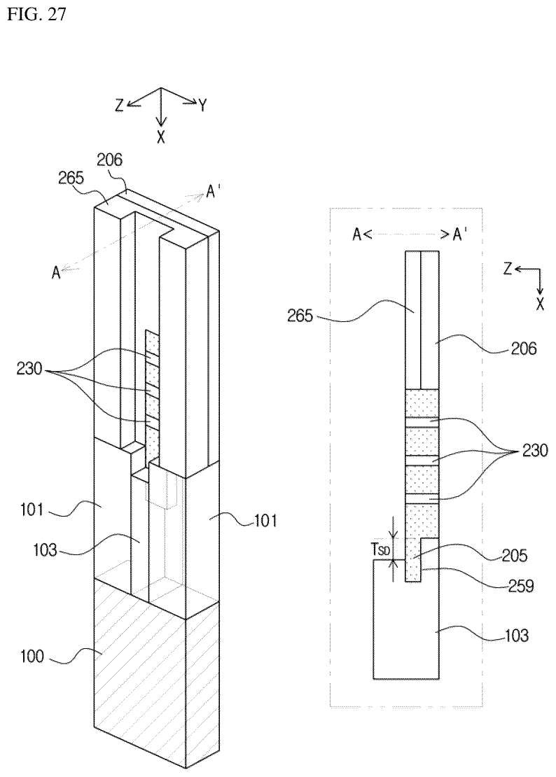

Next, the channels 230 and the sacrificial layers 205 are vertically etched in order to form a source region/a drain region (FIG. 27). In such vertical etching process, additional etching corresponding to T_{SD} additionally occurs on the PTS 103 region for forming a source region/a drain region, and as a result, a structure in which the PTS 103 region and the lowermost sacrificial layer 205 are engaged with each other.

Next, a selective etching process of the sacrificial layers 205 in contact with the channels 230 is performed (FIG. 27), and at this point, etching is performed up to the inside of the trench structured groove of the PTS 103. However, since there is a remaining part 264 (e.g., SiGe residue) in which a portion of the sacrificial layer 205 remains inside the trench structured groove, particularly at the lower end thereof, the remaining part 264 can be completely removed through additional etching or selective etching if necessary.

At this point, the trench structured groove 105 of the PTS 103 provides a substantial space for TIS formation.

Referring to FIG. 27, a difference in height occurs between a region for forming a source region/a drain region and a region in contact with the sacrificial layers 205 in the PTS 103 by over-etching after the selective etching process. However, although not shown, the height difference may not exist between the region for forming the source region/drain region and the region in contact with the sacrificial layers 205 in the PTS 103 if over-etching is not performed during etching for forming the source region/drain region.

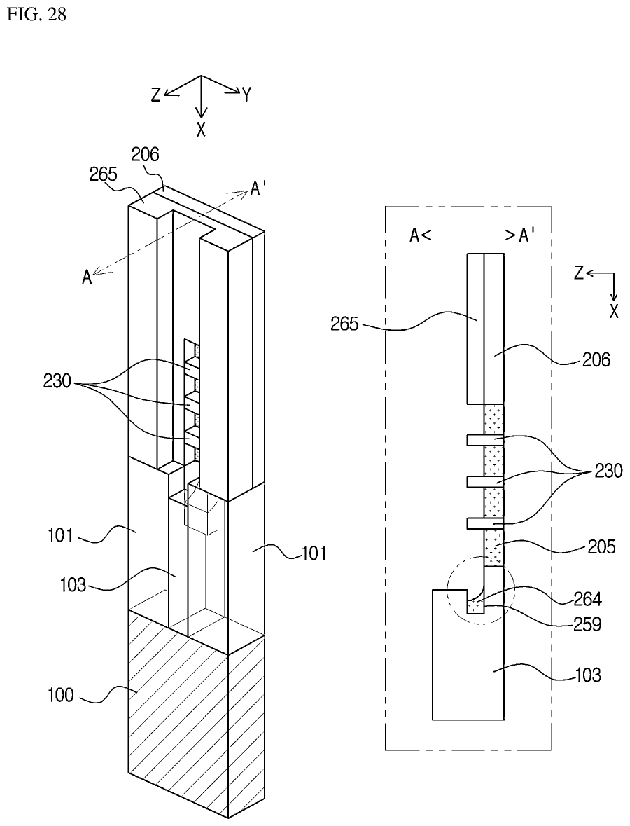

Next, the first and second inner spacers 255 and 256 and the TIS 257 are formed by depositing an insulation material on the trench structure in the PTS 103 and the etching regions of the selectively etched sacrificial layers 205 (FIG. 28).

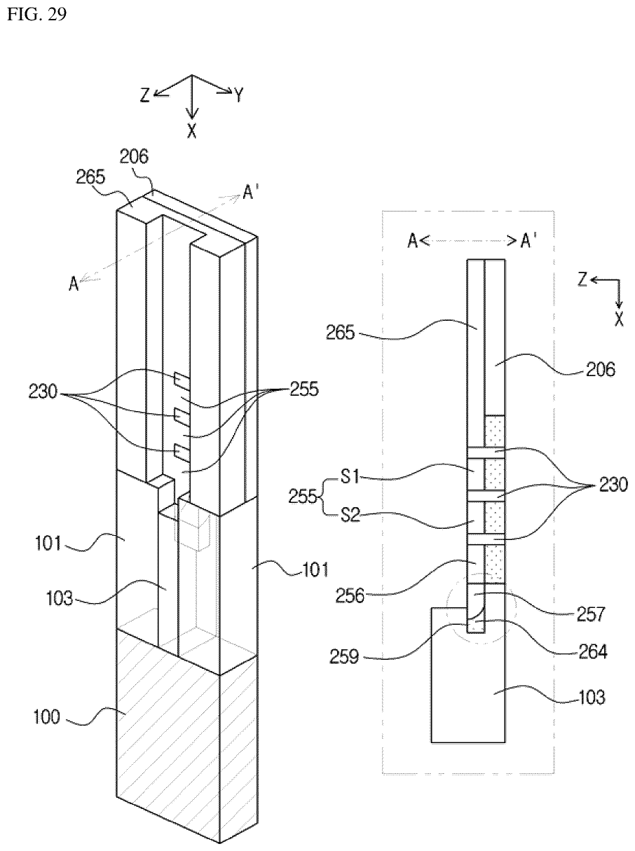

At this point, the TIS 257 may be formed so as to have a height represented by Equation 1 below.

$${H}_{TIS} = {T}_{SD} + {L}_{IS} \qquad [ Equation 1 ]$$

where H_{TIS}, as a height of the TIS, is a vertical length of the TIS with respect to the TIS sidewalls in contact with the source region/drain region, T_{SD} is an over-etched source region/drain region recess depth, and L_{IS} is a horizontal length of the second inner spacer, and is equal to a vertical length from the lowermost point in the vertical direction on the TIS sidewalls in contact with the source region/drain region to the top surface of the substrate located on the bottom of the source region/drain region. The processes from the process of forming the source region 201 and the drain region 202 to the process of forming the contact metal layer 310, which are illustrated in FIGS. 29 to 33, are the same as those described above with reference to FIGS. 16 to 19, the description thereof is omitted below in order to avoid excessive complexity of the specification.

With the TIS, the foregoing GAAFET device having the TIS according to the present disclosure can prevent leakage current from occurring at the lower ends of the channels that cannot be controlled by the gate.

Further, since, as the source region/drain region recesses become deeper, the depth of the trench inner spacers also becomes deeper at the same time, there is the robustness of source region/drain region recess process variables.

Further, a technique for preventing leakage current at the lower ends of the channels by depositing a dielectric layer on the lower ends of the source region/drain region has been previously invented, but compared to the previous invention, the present technique has an advantage in that heat release to the substrate is easy.

Such a technique can be applied to all semiconductor products that utilize three-dimensional GAAFET devices, and it may be expected to increase production yield and reduce costs by reduced power consumption due to reduced leakage current, and the robustness of the source region/drain region recess process variables.

In addition, since the trench patterning process for forming the TIS is performed at the beginning of the manufacturing process of the device, the patterning consistency can be precisely controlled so that there is an advantage in that the technology application possibility and completeness are very high. In addition, since regarding the other processing processes, the existing processing processes may be utilized without any change, the present technique has high applicability.

Although the embodiments of the present disclosure have been described with reference to the accompanying drawings, the present disclosure may be embodied in other specific forms without changing its technical spirit or essential features. Therefore, it should be understood that the embodiments described above are illustrative in all respects and not restrictive.

### DESCRIPTION OF THE REFERENCE NUMERALS

100, 100′, 100″: Substrate
101: STI region
103, 103′, 103″: PTS
201, 202: Source region/drain region
205: Sacrificial layers
206: Dummy gate
220: Silicide
N1, N2, N3, 230: Channels
S1, S2, 255: First inner spacers
256: Second inner spacers
257, 257′: Trench inner spacers (TIS)
259: First groove
259′: Second groove
260: Gate stacks
261: Gate electrode
263: Gate dielectric
264: Remaining part
265: Outer spacer
310: Contact metal layer

### Industrial Applicability

The present disclosure relates to a gate-all-around field effect transistor having trench inner spacers and a method for manufacturing the same.

1.-12. (canceled)

13. A gate-all-around field effect transistor including:
a substrate in which a first groove and a second groove that have a trench structure are formed;
a source region/a drain region formed to be spaced apart from each other on the substrate;
a plurality of channels connecting the source region/drain region;
a plurality of gate stacks having a gate-all-around (GAA) structure surrounding the circumference of at least some of the channels;
first inner spacers included between the source region/drain region and the gate stacks;
second inner spacers located on the bottom of a lowermost channel among the plurality of channels and included between the source region/drain region and a lowermost gate stack; and
trench inner spacers connected to the second inner spacers and vertically extended up to the inside of the first groove and the second groove.

14. The gate-all-around field effect transistor of claim 13, wherein a thickness of a portion, between the first groove and the second groove, of the substrate is the same as or different from that of the other portion of the substrate.

15. The gate-all-around field effect transistor of claim 13, wherein the height HTIS of the trench inner spacers satisfies the following Equation 1:
$$HTIS = TSD + LIS \qquad [ Equation 1 ]$$
where HTIS is a vertical length of the TIS with respect to the TIS sidewalls in contact with the source region/drain region, TSD is an over-etched source region/drain region recess depth, and LIS is a horizontal length of the second inner spacer, and is equal to a vertical length from the lowermost point in the vertical direction on the TIS sidewalls in contact with the source region/drain region to the top surface of the substrate located on the bottom of the source region/drain region.

16. The gate-all-around field effect transistor of claim 15, wherein HTIS is more than 0 nm and not more than 300 nm.

17. The gate-all-around field effect transistor of claim 15, wherein TSD is 0 nm to 200 nm.

18. The gate-all-around field effect transistor of claim 15, wherein LIS is more than 0 nm and not more than 100 nm.

19. The gate-all-around field effect transistor of claim 13, wherein the trench inner spacers include one or more insulating materials selected from the group consisting of SiO2, Al2O3, HfO2, ZrO2, Si3N4, and perovskite oxide.

20. The gate-all-around field effect transistor of claim 13,
further comprising remaining parts vertically extending from the bottom surfaces of the trench inner spacers to the bottom surfaces of the first groove and the second groove.

21. The gate-all-around field effect transistor of claim 20,
wherein the plurality of channels includes Si,
wherein the remaining parts include SiGe.

22. A gate-all-around field effect transistor including:
a substrate;
a punch through stopper (PTS) which is positioned on the substrate and in which a first groove and a second groove that have a trench structure are formed;
a source region/a drain region formed to be spaced apart from each other on the punch through stopper (PTS);
a plurality of channels connecting the source region/drain region;
a plurality of gate stacks having a gate-all-around (GAA) structure surrounding the circumference of at least some of the channels;
first inner spacers included between the source region/drain region and the gate stacks;
second inner spacers located on the bottom of a lowermost channel among the plurality of channels and included between the source region/drain region and a lowermost gate stack; and
trench inner spacers connected to the second inner spacers and vertically extended up to the inside of the first groove and the second groove.

23. The gate-all-around field effect transistor of claim 22, wherein the punch through stopper (PTS) includes impurities of a type opposite to that of the source region/drain region.

24. The gate-all-around field effect transistor of claim 22, wherein a thickness of a portion, between the first groove and the second groove, of the punch through stopper (PTS) is the same as or different from that of the other portion of the punch through stopper (PTS).

25. The gate-all-around field effect transistor of claim 22, wherein the height HTIS of the trench inner spacers satisfies the following Equation 1:
$$HTIS = TSD + LIS \qquad [ Equation 1 ]$$
where HTIS is a vertical length of the TIS with respect to the TIS sidewalls in contact with the source region/drain region, TSD is an over-etched source region/drain region recess depth, and LIS is a horizontal length of the second inner spacer, and is equal to a vertical length from the lowermost point in the vertical direction on the TIS sidewalls in contact with the source region/drain region to the top surface of the substrate located on the bottom of the source region/drain region.

26. The gate-all-around field effect transistor of claim 25, wherein HTIS is more than 0 nm and not more than 300 nm.

27. The gate-all-around field effect transistor of claim 25, wherein TSD is 0 nm to 200 nm.

28. The gate-all-around field effect transistor of claim 25, wherein LIS is more than 0 nm and not more than 100 nm.

29. The gate-all-around field effect transistor of claim 22, wherein the trench inner spacers include one or more insulating materials selected from the group consisting of SiO2, Al2O3, HfO2, ZrO2, Si3N4, and perovskite oxide.

30. The gate-all-around field effect transistor of claim 22, further comprising remaining parts vertically extending from the bottom surfaces of the trench inner spacers to the bottom surfaces of the first groove and the second groove.

31. The gate-all-around field effect transistor of claim 30,
wherein the plurality of channels includes Si,
wherein the remaining parts include SiGe.

32. A gate-all-around field effect transistor including:
a substrate in which a first groove and a second groove that have a trench structure are formed;
a source region/a drain region formed to be spaced apart from each other on the substrate;
a plurality of channels connecting the source region/drain region;
a plurality of gate stacks having a gate-all-around (GAA) structure surrounding the circumference of at least some of the channels;
an outer spacer disposed on side surfaces of the uppermost gate stack of the plurality of gate stacks;
first inner spacers included between the source region/drain region and the gate stacks;
second inner spacers located on the bottom of a lowermost channel among the plurality of channels and included between the source region/drain region and a lowermost gate stack; and
trench inner spacers connected to the second inner spacers and vertically extended up to the inside of the first groove and the second groove;
a contact metal layer disposed on a top of the source region/drain region; and
A silicide disposed between the source region/drain region and the contact metal layer.
